(19) United States
(12) Patent Application Publication
(10) Pub. No.: US 2009/0208669 A1
(43) Pub. Date: Aug. 20, 2009

(54) Apparatus and method for application of a thin barrier layer onto inner surfaces of wafer containers

(75) Inventor: Boris Kesil, San Jose, CA (US)

Correspondence Address: Boris Kesil, 1040 Di Giulio Avenue #200, Santa Clara, CA, 95050, US

(73) Assignee: MultiMetrixs. LLC

(21) Appl. No.: 12/070,044

(22) Filed: Feb. 15, 2008

(51) Int. Cl. C23C 16/505; H05H 1/24

(52) U.S. Cl. 427/569; 118/723 I

(57) ABSTRACT

A method and apparatus for coating the inner walls of polymer-made wafer containers with a thin silicon dioxide barrier film, which is characterized by good washability and possesses high scratch-resistant and wear-resistant properties. In compliance with requirements of high purity, the barrier layer also protects the surfaces of semiconductor wafers from volatile substances of polymer material of the container walls. The apparatus comprises a base plate and an RF antenna unit that is inserted into the preliminarily sealed and evacuated container. The apparatus is connected to the front side of the container through a standard mechanical interface provided on the facing side of the apparatus. The barrier layer is deposited with the use of a plasma-enhanced chemical-vapor-deposition process as a result of a plasma-chemical reaction in a working gas comprising a mixture of silane with excess oxygen.

### FIELD OF THE INVENTION

The present invention relates to the field of semiconductor production, and more particularly, to devices for storage and transportation of semiconductor wafers used for the manufacture of semiconductor devices in a mini-environment. More specifically, the invention relates to a method and apparatus for application of barrier layers onto the inner surfaces of molded and sealable wafer containers, such as FOUPs, FOSBs, etc., for improving cleanliness, washability, scratch-resistance, and wear-resistance of the inner walls of such containers. The barrier layer is made in the form of SiO₂ deposited from plasma by the PECVD process with the use of an apparatus having a three-dimensional RF antenna of high conformity to the shape of interior of the container.

### BACKGROUND OF THE INVENTION

It is well known that semiconductor processing requires operation under very clean conditions. At the present time the requirement for purity of semiconductor wafers is very stringent, and, therefore, the number of contaminant particles that are introduced into the wafer container from outside or that are formed inside the wafer container must be maintained at the minimal possible level.

Contamination is the single biggest cause of yield loss in the semiconductor industry. As the size of integrated circuitry has continued to be reduced, the size of particles, which can contaminate an integrated circuit, has also become smaller, making minimization of contaminants all the more critical. Therefore, one important direction of maintaining wafers in an ultra-clean state is the elimination of sources that produce foreign or contaminated particles, which can precipitate onto the wafer surface.

Silicon wafers are handled in special plastic cassettes and are carried in special, closed containers. Despite the fact that wafer transportation and processing must be contamination free, these processes introduce organic contaminants and particles. In order to improve cleanliness of the semiconductor production, the so-called mini-environment has been introduced. This means that the wafers are no longer handled in open cassettes but rather in closed, clean boxes that are opened only inside the processing equipment and in closed spaces having a high degree of cleanliness. Here, the term “wafer container” pertains to the sealable “closed boxes” used in semiconductor production and is known as SMIF (Standard Mechanical InterFace) boxes, FOUP boxes (Front Opening Unified Pod), FOSB (Front Opening Shipping Boxes), etc.

SMIF represents boxes that include an open cassette, which is unloaded through the bottom of the SMIF pod. For 300 mm silicon wafers, the design of the mini-environment boxes has been changed and now becomes the state of the art. These boxes are opened from the front side, and the equipment robot unloads the wafers directly from the FOUP. FOSB has a simpler construction and is designed only for transportation.

Contaminants in the form of particles can be generated by abrasion, such as rubbing or scraping of the carrier with the wafers or disks, with carrier covers or enclosures, with storage racks, with other carriers, or with processing equipment. Additionally, particulates such as dust can be introduced into enclosures through openings or joints in the covers and/or enclosures.

Containers are generally configured for arrangement of wafers, or disks, in slots and for support of the wafers or disks by or near their peripheral edges. The wafers, or disks, are conventionally removed from the containers upwardly or laterally in a radial direction. The containers may have a shell portion with a lower opening, a door to latch into the lower opening, and a discrete carrier that rests on the door. These configurations, known as SMIF pods, are illustrated in U.S. Pat. Nos. 4,995,430 issued in 1991 to A. Borona, et al, and 4,815,912 issued in 1989 to G. Money, et al. Additionally, FOUP- or FOSB-type wafer container assemblies can have front openings with doors that latch onto front openings, which are described in, for example, U.S. Pat. No. 6,354,601 issued to D. Krampotich, et al, in 2002.

In certain configurations, the bottom covers or doors, front doors, or the container portions have been provided with openings or passages that facilitate the introduction and/or exhaustion of gases such as nitrogen or other purified gasses into the wafer container assemblies to displace ambient air that might have contaminants. Furthermore, some containers employ filter plugs to reduce the amount of particulate contaminants that enter the container assemblies during purging. However, conventional attachment and sealing between the operation element, i.e., the filter, and the housing of the seal are by way of rigid plastic housings and O-rings. Wafer containers known in the art have also used various connection or coupling mechanisms for fluidly interfacing the flow passages of the wafer containers to the fluid supply and pressure or vacuum sources. Such attachment and sealing requires specialized components, which may be of complex configuration.

However, wafer containers cannot completely protect wafers from particulate contamination. For example, contamination can be generated and introduced to wafers or substrates through handling equipment. For example, particulates can be generated mechanically by wafers as they are inserted into and removed from wafer carriers, as doors are attached and removed from the carriers, or as generated chemically in reaction to various processing fluids. Contamination can also be the result of out-gassing on the carrier, biological sources due to human activity, etc. Contamination can also accumulate on the exterior of a carrier as the carrier is transported from station to station during processing. In view of the above, wafer containers are often subjected to cleaning by washing. However, surfaces of polymer materials are not easily washable. Furthermore, polymeric materials are soft and easily scratchable, and the thus-formed scratches or microcracks that occur because of deformation and deterioration serve as sources of accumulated contaminants, which cannot be easily removed by washing.

Other examples of wafer containers of various types which are used in industry today and to which the present invention can be applicable are the following: a wafer container of the type shown in the drawings of U.S. Pat. No. 6,926,017 issued in 2005 to D. Halbmaier and relating to a wafer container washing apparatus; a front-opening substrate container with a bottom plate disclosed in U.S. Pat. No. 7,201,276 to J. Burns, et al, in 2007; a substrate container described in U.S. Pat. No. 7,316,325 issued in 2008 to J. Burns, et al, and a substrate storage container described in U.S. Patent Application Publication No. 20070151897 (inventors: T. Nakayama, et al) wherein wafer-supporting ribs are made not in the form of a removable cartridge but in the form of ribs on the inner walls of the container. These ribs are formed by a plurality of parallel horizontal plates embedded in the material of the container casing.

Attempts have been made heretofore to develop wafer carriers with means for eliminating particle-forming sources. For example, U.S. Patent Application Publication No. 20060216942 published in 2006 (inventor: G. Kim) discloses a wafer-supporting cartridge having a reduced area of contact between the carrier and the wafer surface. When the contact area between the carrier and the wafer is large, static electricity and friction-induced formation of foreign particles occur, causing foreign particles to adhere to the wafer. Moreover, when foreign particles adhere to a wafer, the yield in semiconductor manufacturing is also reduced. The aforementioned invention provides construction of the wafer-storage box with a cartridge that has reduced wafer-supporting surfaces because of its geometry.

Many other patents and patent applications aimed to solve the problem of cleanliness by providing particle-proof wafer containers are known (e.g., U.S. Pat. No. 5,780,127 issued in 1998 to K. Mikkelsen, U.S. Pat. No. 7,316,325 issued in 2008 to J. Burns, et al, etc.).

To improve the yield of devices on a semiconductor production line is very important. The major cause low yield is the existence of the aforementioned contaminant particles consisting of dust, organic substances, and so forth.

It is therefore proposed, e.g., in U.S. Pat. No. 6,926,029 issued in 2005 to K. Inoue, et al, to use the C-type SMIF system provided with a sealed wafer pod in place of an open cassette for use in semiconductor wafer transportation. By means of the wafer pod, it is possible to maintain dust-free wafers because the wafers can be accepted, transported, and stored in a sealed box implemented with the wafer pod. Furthermore, even if the environment around the process chambers is not purified, it is possible to transport the wafer between the process chambers without contamination. A container for storing substrates proposed in U.S. Pat. No. 6,926,029 is composed of a box for accommodating the substrates and a closure member for closing and sealing the box by tightly fixing the closure member to the opening of the box. The container is provided with means for temporarily storing a sealing gas and introducing the sealing gas into the box. Also, the container for the storage of substrates is provided with means for temporarily forming a low-pressure space for the purpose of evacuating the gas inside the box by transferring the gas to the low-pressure space.

According to U.S. Pat. No. 4,739,882 issued in 1988 to M. Parikh, et al, the wafer container is provided with a removable liner for surrounding the cassette in order to protect it from contamination with airborne particles of dust and chemicals. In a preferred embodiment, the liner comprises a top liner located between the box top and the box base; the liner is made of a semi-rigid material that maintains a concave shape and surrounds the cassette or holder independently of any mechanical support. In another preferred embodiment, the liner further includes a base liner that is adapted to fit on the surface of the box door. The base liner has a sealing lip around its perimeter for exerting force between the base and the box door to encourage a dust-tight seal therebetween. The top liner includes a compression means for exerting force between the box top and box base. The top liner sits on the box base.

Typically, the top liner is a thin, flexible plastic liner that requires mechanical support to be held in a tent shape. The top liner is made from a non-contaminating material, such as a thermoplastic material, examples of which are vinyl, acrylic, and fluoroplastic. Thermoplastics can be conformed by well-known techniques into relatively thin or thick transparent films. In any embodiment, such thermoplastic films are manufactured according to processes that result in a reduced number of contaminant particles. Fluoroplastic is a generic name for polytetrafluoroethylene and its copolymers. One such well-known fluoroplastic is TEFLON® (a trademark of DuPont).

The liners are essentially disposable. Typically, a liner is destroyed after one or several uses. It is expected that a liner would last from one week to three weeks under expected processing conditions. Although the liner environment is as clean as possible, contaminants generated by bumping are present, as mentioned above. Contaminants collected on the external surface of the liner cause the liner to become dirty and a potential source of contamination for subsequent processing steps when opening the SMIF box. By replacing the liner, the container is restored to its original “clean” state without the need to replace the entire SMIF box, itself. Although particulate contamination was significantly reduced because of the presence of such liners, contaminants were still noticed on the wafer surface.

Nevertheless, foreign particles of contaminants introduced into the wafer container from outside or formed inside the wafer as a result of friction, etc., are not the only source of wafer contamination. It is known that wafer containers are typically formed from injection-molded plastics such as polycarbonate (PC), acrylonitrile butadiene styrene (ABS), polypropylene (PP), polyethylene (PE), perfluoroalkoxy (PFA), and polyetheretherketone (PEEK). It must be recognized that a material that is ideal for one carrier function is typically not the ideal material for a different function of the same carrier. For example, PEEK is a material that has ideal abrasion-resistance characteristics for wafer contact portions but is difficult to mold and is cost-prohibitive relative to other plastics. However, all of these materials have a fundamental disadvantage: a polymer substance contains light and short molecules, such as monomers, and their fragments, such as free radicals. These molecules can diffuse through the polymer surface and exit into outer space, which in reality continuously happens during the entire lifetime of a polymer. Such products of diffusion usually are deposited onto the wafer surface where they form island-like structures and even continuous organic films. Over an extended period of wafer storage in a plastic container, the thickness of such a deposition may reach tens of angstroms. This disadvantage results in the necessity to introduce additional procedures of contamination removal in between critical operations. Replacement of the polymers by fused silica, glass, and/or other materials not having said problems is, in general, cost-ineffective and complex.

On the other hand, it is known to apply protective layers of silicon dioxide (hereinafter referred to as “SiO₂”) onto the polymeric surfaces by plasma-enhanced chemical-gas-phase deposition (PECVD) from a gaseous organosilicon with excess oxygen. Such a process is described, e.g., in U.S. Pat. No. 6,180,191 issued in 2001 to J. Felts. The process is exemplified by application of a gas-proof and liquid-proof barrier coating onto the inner surfaces of bottles. A gas inlet, which also serves as a counter electrode, is located inside a vacuum chamber made of an electrically insulating material. A container is mounted on a mandrel that is mounted on the gas inlet. The chamber is evacuated to subatmospheric pressure. A process gas is then introduced into the container through the gas inlet. The process gas is ionized by coupling RF power to the main electrode located adjacent to the exterior surface of the chamber and to the gas inlet, which deposits a plasma-enhanced chemical-vapor-deposition (PECVD) thin film onto the interior surface of the container.

However, the method and apparatus of the type mentioned in U.S. Pat. No. 6,180,191 are not applicable for efficient application of uniform protective coatings onto the inner walls of wafer containers because in the apparatus of the above patent, the coating operation is carried out in a vacuum chamber that contains a large number of small-volume bottles or similar small containers. On the other hand, a wafer container is an object that occupies a volume approximately ten times greater than a bottle processed with the apparatus and method of U.S. Pat. No. 6,180,191. The processing of several large objects in vacuum would require a vacuum chamber of such a huge size that it would be economically unjustifiable and extremely non-productive. Furthermore, the shape of the antenna described in the aforementioned patent cannot generate plasma that would produce uniform coating and that would conform to the inner walls of the container.

Additionally, the applicant is unaware of any known method and apparatus for coating the inner walls of wafer containers that are molded from polymer and have a thin barrier film that is easily washable, scratch- and wear-resistant, and not penetrable to volatile organic radicals and monomers present in the polymeric material of the container.

### OBJECTS AND SUMMARY OF THE INVENTION

It is an object of the present invention to provide a method and apparatus for coating the inner walls of a sealable wafer container molded from a polymer material with a thin barrier layer, such as an SiO₂ layer, to prevent diffusion of free radicals of the polymer material of the container into the interior space of the container that contains the semiconductor wafers. It is another object to provide the aforementioned method and apparatus for coating the inner walls of the wafer containers with the aforementioned barrier SiO₂ layer, which is easily washable and which is resistant to wear and scratching. A further object is to apply the aforementioned layer by the PECVD method. A still further object is to provide the apparatus of the invention that generates SiO₂-depositing plasma having extremely high conformity to the shape of the inner surface of the wafer container and capable of forming an SiO₂ film of highly uniform thickness.

The apparatus of the invention comprises a base plate that supports a three-dimensional antenna unit consisting of five flat, spiral RF antenna elements which together form a parallelepiped or cube-like body that closely corresponds to the shape of the container interior defined by the inner walls of the container. A portion of the base plate that surrounds the antenna forms a flange that matches the shape of the sealable-container opening and is capable of closing and sealing this opening when the three-dimensional RF antenna is inserted into the inner space of the container. An exhaust pipe that passes through the base plate of the antenna unit connects the interior of the sealed container with the pipe of a vacuum system in order to create the vacuum required for operation of the apparatus in a plasma-enhanced chemical-vapor-deposition mode used for depositing a thin barrier layer made from SiO₂ onto the inner walls of the container. Another pipe that is introduced into the interior of the wafer container is intended to supply a working gas, e.g., a mixture of silane with excess oxygen needed for carrying out a plasma-chemical reaction in the vacuum of the container.

When a vacuum is created inside the sealed container, the working gas mixture is fed to the container, the antenna unit is energized, and plasma is excited inside the container. Since the configuration of the antenna body closely matches the shape formed by the inner walls of the container, the portion of the plasma between the antenna and the container walls acquires good conformity to the treated surfaces.

In order to ensure a reliable vacuum in the container during operation, the area of contact between the base plate and the face surface of the container is sealed with a sealing element placed into a groove formed in the front surface of the base plate that corresponds to the standard mechanical interface of FOUPs, FOSBs, etc.

The container may be secured to the base plate by a clamping mechanism, the construction of which depends on the specific shape and structure of the corresponding elements of the container.

Since the cover forms one of the inner walls of the container in a sealed state, the barrier layer must also coat the inner side of the cover. The cover-coating operation is carried out with the use of the same apparatus that is used for coating the walls of the container. For this purpose, only one antenna element is energized, and the cover is fixed in a special jig.

The barrier layer comprises SiO₂ film obtained by deposition in a vacuum from gaseous organosilicon with excess oxygen. The coating film has a thickness ranging from 100 to 500 Angstroms. Each antenna element comprises a flat spiral turn made from a material of high electrical conductivity, e.g., from copper, and each RF antenna element is isolated with a ceramic material, e.g., a machineable glass ceramic known under trademark MACOR® registered by Morgan Advanced Ceramics, PA, USA. MACOR® has a continuous-use temperature of 800° C. and a peak temperature of 1000° C. Its coefficient of thermal expansion readily matches most metals and sealing glasses. It is non-wetting, exhibits zero porosity, and, unlike ductile materials, won't deform. It is an excellent insulator at high voltages, various frequencies, and high temperatures. When properly baked out, it won't outgas in vacuum environments. It can be quickly and inexpensively machined into complicated shapes and precision parts with ordinary metal working tools, and it requires no post-firing after machining.

The first and second terminals of each antenna element are exposed from the insulating ceramic enclosure, and the lead wires from the terminals are guided through the base plate by means of respective feedthroughs to a commutator and impedance-matching unit, which, in turn, is connected to an RF power supply source.

The method of the invention for coating the inner walls of a wafer container with an easily washable, wear- and scratch-resistant barrier layer that is impermeable to organic volatile substances of polymer comprises the following steps: providing an apparatus having an antenna unit with a configuration that matches the shape defined by the inner walls of the sealable wafer container; inserting and sealing the antenna unit into the interior of the wafer container so that the elements that form the antenna unit are arranged in proximity to the inner walls of the container; creating a vacuum in the interior of the sealed container by evacuating air from the container; supplying a working gas into the interior of the container; energizing the antenna elements for exciting plasma inside the container that closely conforms to the shape defined by the inner walls of the container; and depositing a continuous and uniform barrier layer on the inner walls of the container.

The main distinguishing feature of the method of the invention is that, in contrast to other known PECVD processes, the deposition process of the invention is carried out in a vacuum that is induced inside the container, itself, instead of the vacuum chamber into which the containers, such as bottles, are placed for treatment. Another distinguishing feature is the shape of the antenna unit, which closely conforms to the shape defined by the inner walls of the container. A still further distinctive feature is provision of a base plate that is provided with a standard mechanical interface used in the industry for closing and sealing the wafer containers.

### BRIEF DESCRIPTION OF THE DRAWINGS

FIG. 1 is a three-dimensional view of a wafer container suitable for the purposes of the present invention.

FIG. 2 is a three-dimensional view of the cover of the container shown in FIG. 1.

FIG. 3 is a fragmental sectional view along line III-III of FIG. 1 with exaggerated thickness of the coating layers.

FIG. 4 is a three-dimensional view of a wafer container of another modification suitable for the purposes of the invention.

FIG. 5 is a fragmental sectional view along line V-V of FIG. 4.

FIG. 6 is a three-dimensional view of the apparatus of the invention.

FIG. 7 is a three-dimensional view of the antenna element used in the apparatus of the invention.

FIG. 8 is a vertical sectional view of the apparatus of the invention along line VIII-VIII in FIG. 6 in a working position for treating container walls.

FIG. 9 is a vertical sectional view of the apparatus of the invention in a working position for treating the cover of the container.

### DETAILED DESCRIPTION OF THE INVENTION

To better understand the principle of the present invention, it is advantageous first to describe the wafer containers that constitute an object of treatment with the apparatus of the invention.

Although the wafer container of the present invention may be of any suitable type, hereinafter it will be exemplified by a wafer container known as a FOUP, which typically has the shape of a box having one side open for loading and unloading wafers, manually or with the use of a mechanical arm of an industrial robot.

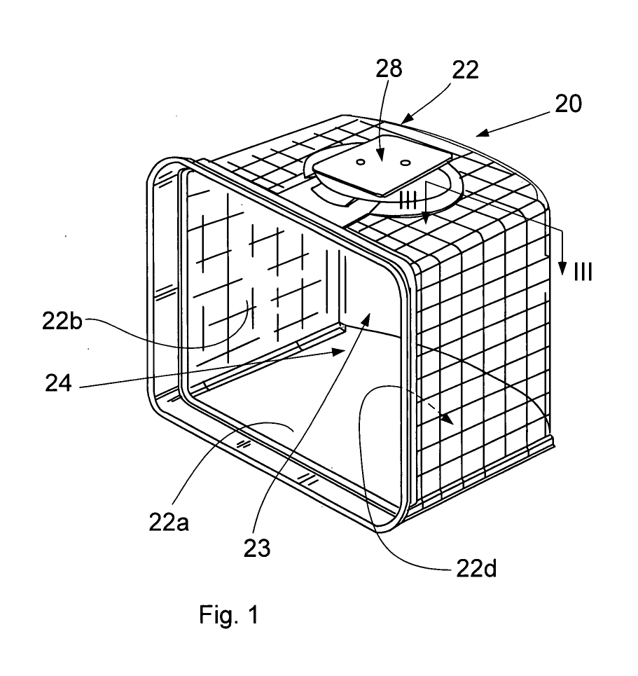

FIG. 1 is a three-dimensional view of a FOUP 20 suitable for the purposes of the present invention. The wafer containers of the type described below are beyond the scope of the present invention and constitute a subject of co-pending patent application Ser. No. ______ of the same application filed on ______

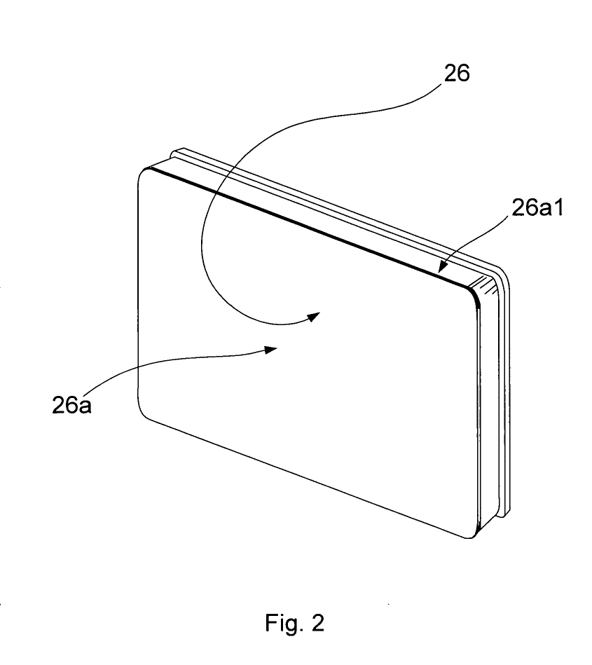

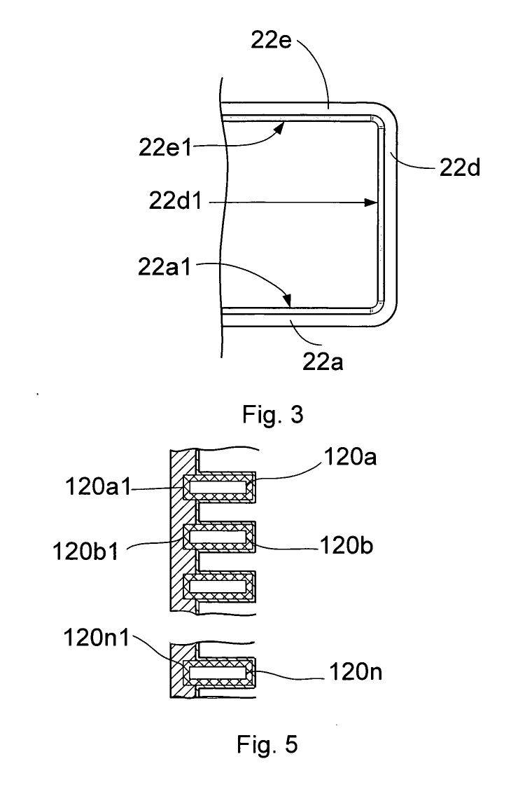

FOUP 20 is made in the form of a box 22 with an open front side 24 and with the cover removed. The cover 26 is shown in FIG. 2, which is a three-dimensional view. FIG. 3 is a fragmental sectional view along line III-III of FIG. 1 with exaggerated thickness of the coating layers. In FIG. 1, reference numeral 23 designates the container interior.

The wafer container shown in FIGS. 1, 2, and 3 is a FOUP with smooth inner walls 22a, 22b, 22c, 22d, and 22e and is intended for receiving the wafers pre-assembled with the wafer-holding cartridge, which is not shown in the drawings since the structure of this cartridge is beyond the scope of the present invention.

Reference numeral 28 designates a device for engagement of the FOUP 20 with a robotic flange of a container-transporting device (not shown). Furthermore, the FOUP 20 may have sealable openings formed in the walls for various technological purposes (not shown) of the wafer-treating processes.

According to the invention, the inner walls 22a, 22b, 22c, 22d, and 22e of the FOUP 20 are coated with thin wear- and scratch-resistant and easily washable coatings, e.g., SiO₂, which are impermeable to volatile products that can be generated in the polymer material of the container walls 22a, 22b, 22c, 22d, and 22e. The thickness of the coating must be sufficient to form a physical barrier against diffusion of free radicals, monomers, and low-molecular-weight fragments of the polymer from which the FOUP is made. SiO₂ layers are shown only on the walls 22a, 22d, and 22e, which are seen in FIG. 3 and are designated by reference numerals 22a1, 22d1, and 22e1. Although the coatings formed on the other inner walls of the FOUP 20 are not shown, it is assumed that similar SiO₂ barrier layers are also formed on the remaining inner walls 22b and 22c.

It should be noted that typically SiO₂ layers 22a1, 22b1, 22c1, 22d1, and 22e1 are continuous coatings having a thickness ranging from 100 to 500 Angstroms, although the upper limit of the thickness is not limited by 500 Angstroms and is selected with reference to factors such as cost, duration of deposition process, and resistance to wear and scratching.

The cover 26 shown in FIG. 2 can be molded from the same polymer material as the FOUP casing. The cover 26 has a face surface 26a, which in the FOUP-closing position of the cover 26, sealingly closes and faces the interior of the FOUP 20. The cover 26 has a flange 26b, the shape of which corresponds to the configuration of the FOUP opening 24. All characteristics mentioned above with regard to the coating also relate to the FOUP cover 26, i.e., the face surface 26a of the cover 26 is coated with a continuous SiO₂ barrier layer 26a1 having a thickness ranging from 100 to 500 Angstroms. This layer is resistant to scratching and wear and is easily cleanable.

Since the interior of the FOUP 20 is protected from penetration of the volatile contaminants of the FOUP-wall material into the interior of the FOUP 20, it becomes possible to mold the FOUP from a low-grade polymer that may have a higher content of volatile low-molecular fragments, monomers, and free radicals than polymers of higher grades normally recommended for manufacturing wafer containers such as the FOUP 20.

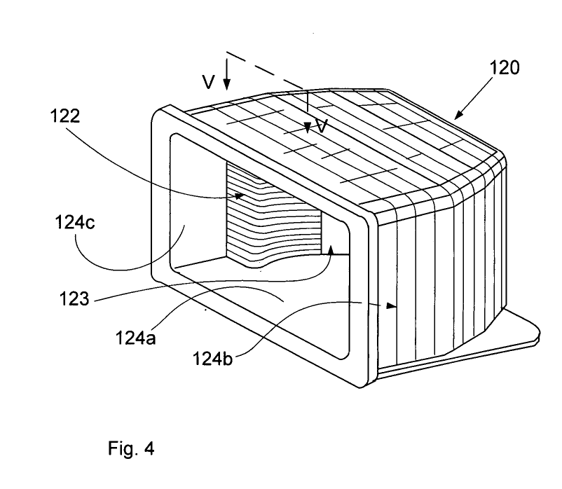

FIG. 4 is a three-dimensional view of the FOUP 120 of another modification suitable for the purposes of the invention. This FOUP has wafer-supporting edges 122 formed on the inner walls of the FOUP 120 by pre-coated strips 120a, 120b, . . . 120n inserted into slots formed in the pre-coated inner walls of the container. In FIG. 4, reference numeral 123 designates the container interior. FIG. 5 is a fragmental sectional view along line V-V of FIG. 4. In order not to complicate the drawing, in FIG. 4 the strips are shown only on one inner wall of the FOUP 120. FIG. 5 is a fragmental sectional view along line V-V of FIG. 4. The cover for the FOUP 120 is not shown because it can be the same as one shown in FIG. 2.

Similar to the FOUP 20 of the previous modification, the FOUP 120 of FIGS. 4 and 5 has inner walls such as 124a, 124b, 124c, . . . pre-coated with thin wear- and scratch-resistant, easily washable layers, e.g., of a SiO₂, which are impermeable to volatile products that can be generated in the polymer material of the container walls 124a, 124b, 124c . . . . The thickness of the coatings must be sufficient to form physical barriers against diffusion of free radicals, monomers, and low-molecular-weight fragments of the polymer from which the FOUP is made. The SiO₂ barrier layer is present not only on the inner surfaces of the FOUP walls but also on all surfaces of the strips 120a, 120b, . . . 120n, which are exposed to the interior of the FOUP 120. The SiO₂ layers have a thickness ranging from 100 to 500 Angstroms, although the upper limit of the thickness is not limited by 500 Angstroms and is selected with reference to such factors as cost, duration of deposition process, and resistance to wear and scratching. The coating layer of SiO₂ is not shown in FIG. 4 but is represented by a single continuous coating layer 128 in FIG. 5.

It is understood that in the construction with wafer-supporting edges 120a, 120b, . . . 120n, it will be difficult or impossible to provide the coating layer 128 of the same uniform thickness in the areas between the wafer-supporting edges 120a, 120b, . . . 120n as in the smooth inner walls of the container shown in FIGS. 1, 2, and 3. Therefore, according to the invention, the pre-coated inner walls 124a, 124b, 124c, . . . of the container have parallel slots 120a1, 120b1, . . . 120n1 for insertion and fixation of wafer-supporting edges 120a, 120b, . . . 120n formed by strips 120a, 120b, . . . 120n pre-coated with the same protective film of SiO₂ prior to insertion of the strips into the FOUP. Use of the pre-coated wafer-supporting edges 120a, 120b, . . . 120n will make it possible to obtain a continuous SiO₂ barrier coating layer 128.

Having described the wafer containers suitable for the purposes of the invention, let us consider the apparatus of the invention for depositing onto the inner walls of a wafer container a barrier layer which is impermeable to volatile organic fragments of polymer from which the container is made and which possesses properties such as washability and resistance to scratching and wear.

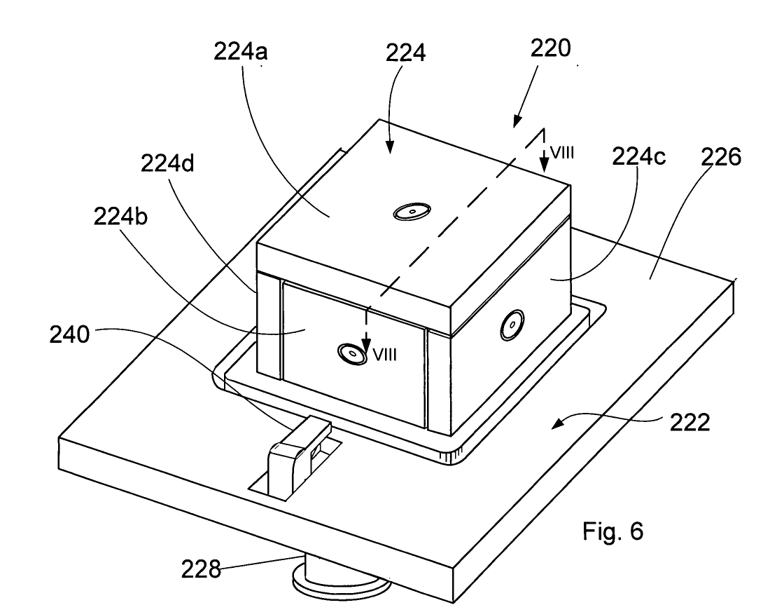

As shown in FIG. 6, which is a three-dimensional view of the apparatus of the invention, the apparatus that in general is designated by reference numeral 220 comprises a base plate 222 that supports a three-dimensional antenna unit 224 consisting of five flat spiral RF antenna elements, only four of which, i.e., 224a, 224b, 224c, and 224d, are seen in FIG. 6. The aforementioned five flat spiral RF antenna elements are connected to each other to form a body that comprises a cube or parallelepiped.

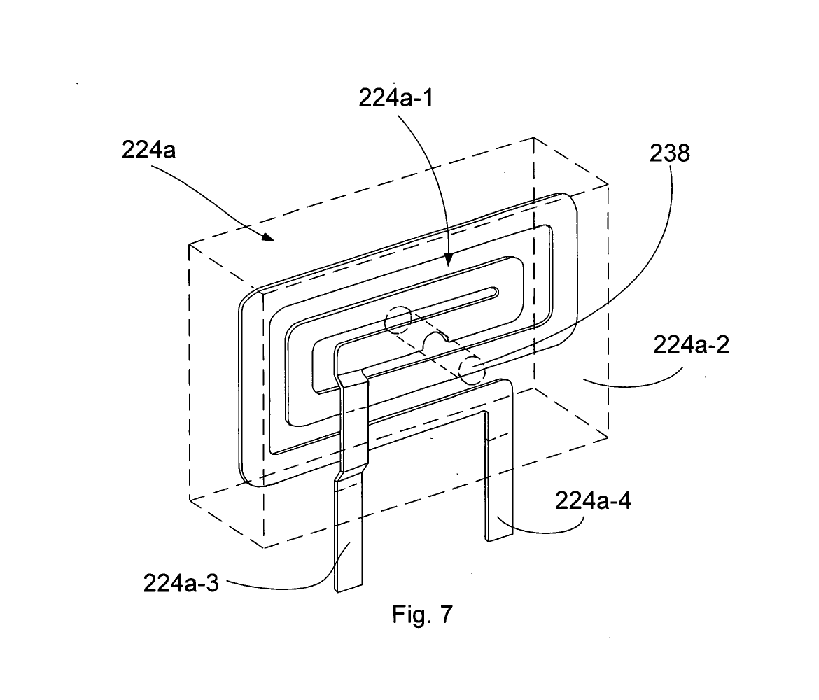

The antenna element is shown in FIG. 7. Since in their structure all antenna elements are similar, only one of them, e.g., the antenna element 224a, will be considered with reference to FIG. 7. The antenna element 224a comprises a flat spiral turn 224a-1 made from a material of high electrical conductivity, e.g., from copper, which is isolated with a ceramic material 224a-2, e.g., a machineable glass ceramic known under the trademark MACOR® registered by Morgan Advanced Ceramics, PA, USA. MACOR® has a continuous-use temperature of 800° C. and a peak temperature of 1000° C. Its coefficient of thermal expansion readily matches most metals and sealing glasses. It is non-wetting, exhibits zero porosity, and, unlike ductile materials, won't deform. It is an excellent insulator at high voltages, various frequencies, and high temperatures. When properly baked out, it won't outgas in vacuum environments. It can be quickly and inexpensively machined into complicated shapes and precision parts with ordinary metal working tools, and it requires no post-firing after machining.

In FIG. 7, reference numerals 224a-3 and 2224a-4 designate the first and second terminals of the flat spiral turn 224a-1, and reference numeral 238 designates a through-opening that passes across the antenna element 224a for delivery of the working gas to the area between the antenna element and the mating inner wall of the container 20.

As shown in FIG. 6, altogether these elements form a parallelepiped-like or cube-like body that closely corresponds to the shape of the container interiors 23 and 123 (FIGS. 1 and 4) defined by the inner walls of the container. A portion 226 of the base plate 222 that surrounds the antenna unit 224 forms a flange that matches the shape of the sealable-container opening 24 (FIG. 1) and is capable of sealing this opening when the three-dimensional RF antenna unit 224 is inserted into the inner space 23 (FIG. 1) of the container 20. In fact, the aforementioned flange and seal may correspond to the standard mechanical interface used in the industry.

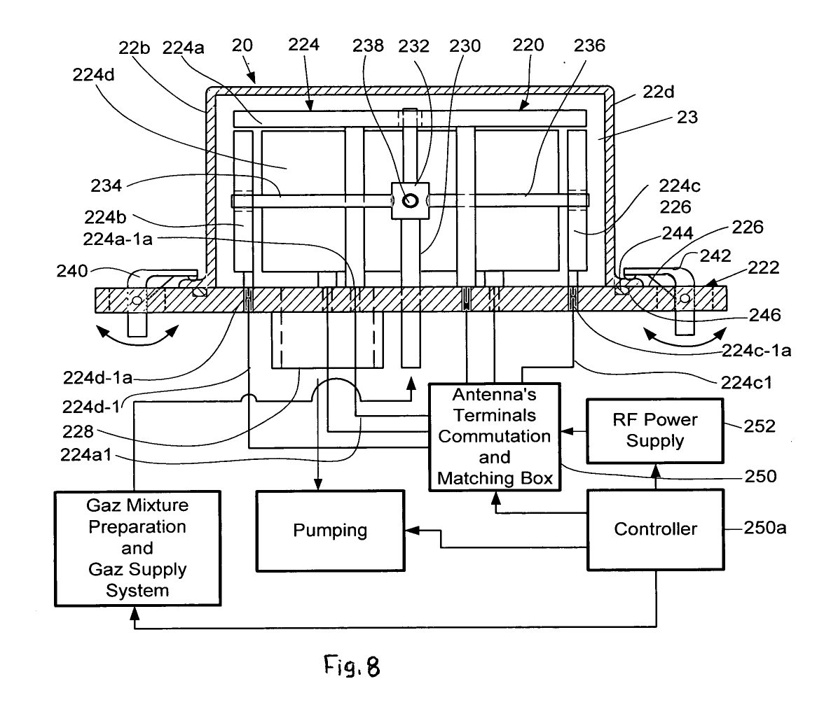

FIG. 8 is a vertical sectional view of the apparatus 220 along line VIII-VIII of FIG. 6. It can be seen that the apparatus is provided with an exhaust pipe 228 that passes through the base plate 222 of the antenna unit 224 and connects the interior 23 (FIG. 1) of the sealed container 20 with the pipe of a vacuum system 228a (FIG. 8) in order to create a vacuum required for operation of the apparatus 220 in a plasma-enhanced chemical-vapor-deposition mode used for depositing thin barrier layers 22e1, 22d1, 22a1, etc., (FIG. 3) onto the respective inner walls 22e, 22d, 22a1, etc., of the container 20 (FIG. 1) made from a polymer material.

Another pipe 230 (FIG. 8) that is introduced into the interior 23 of the wafer container 20 (FIGS. 1 and 7) is intended for the supply of a working gas, e.g., a mixture of silane with excess oxygen needed for carrying out the plasma-chemical reaction in the vacuum of the container 20. The working-gas supply pipe 230 is connected to a working-gas supply source 230a. For uniform distribution of the working gas in the volume of the container between the inner walls of the container and the antenna elements 224a, 224b, 224c, 224d (FIG. 6) and 224e (FIG. 8), the gas-feed pipe 230 has a distribution box 232 with branched pipes 234, 236 and two additional pipes, which are not seen in the drawings since they are oriented perpendicular to the plane of the drawing and are connected to the opening 238 of the distribution box (FIGS. 7 and 8).

The flange portion 226 of the base plate 222 supports clamping mechanisms 240 and 242 (FIGS. 6 and 8) for securing the wafer container 20 to the base plate 222. A sealing element 244 is placed into a groove 246 that is formed in the area of the base plate intended for supporting the front end of the container. The clamping mechanisms may have any construction that corresponds to the mating structural elements of the container 20. In fact, the sealing engagement of the open end of the container 20 with the base plate 222 through the sealing element 244 may comprise a standard mechanical interface (SMIF) system, e.g., such as a vacuum-integrated SMIF system, which is disclosed in U.S. Pat. No. 5,752,796 issued in 1988 to R. Muka and shown in more detail in FIG. 3 of the aforementioned patent.

The first and second terminals of each antenna element, such as terminals 224a-3 and 224a-4 shown in FIG. 7, are exposed from the insulating ceramic enclosure 224a-2. The lead wires 224d-1, 224a-1, 224c-1, etc., of respective antenna elements 224d, 224a, 224c, etc., that extend from the terminals of the respective antenna elements 224d, 224a, 224c, etc., are guided through the base plate 222 via respective feedthroughs 222d-1a, 224a-1a, 224c-1a, etc., to a commutator and impedance-matching unit 250, which, in turn, is connected to an RF power supply source 252 and to a controller 250a that can switch the antenna unit between the first state, in which the RF power supply source 252 is connected to all five antenna elements, and the second state, in which the RF power supply source 252 is connected only to the upper RF antenna element 224a.

For application of the barrier layer 22e1, 22d1, 22a1, etc. (FIG. 3) onto the respective inner walls 22e, 22d, 22a1, etc., of the container 20 (FIG. 1) made from a polymer material, the container 20 is placed onto the base plate 222 so that the end face on the front end of the container rests on the sealing element 244. The container 20 is secured to the base plate 222 so that the interior 23 of the container is sealed by the sealing element 244. Air is evacuated from the interior of the container by a vacuum system 222a (FIG. 8) via the exhaust pipe 228 (FIGS. 6 and 8).

When a vacuum is created inside the sealed container 20, the working gas mixture consisting of a gaseous organosilicon, e.g., gaseous silane, is fed into the container 20 through the gas-feed pipe 230 (FIG. 8), the antenna unit 220 is energized, the plasma is excited inside the container 20, and the SiO₂ barrier layer having a thickness of 100 to 500 Angstroms is formed on the inner surfaces of the container as a result of the PECVD process that occurs in the vacuum of the sealed container 20.

Since the configuration of the antenna unit 220 closely matches the shape formed by the inner walls 22e, 22d, 22a1, etc., of the container 20, the portions of plasma between the antenna elements 224a, 224b, 224d, . . . etc., and the container walls 22e, 22d, 22a1, etc., conform well to the treated surfaces.

Upon completion of the operation, the antenna unit 220 is de-energized, connection with the vacuum system is closed, and the container 20 is released from the base plate 222 by unlocking the clamps 240 and 242 (FIG. 8).

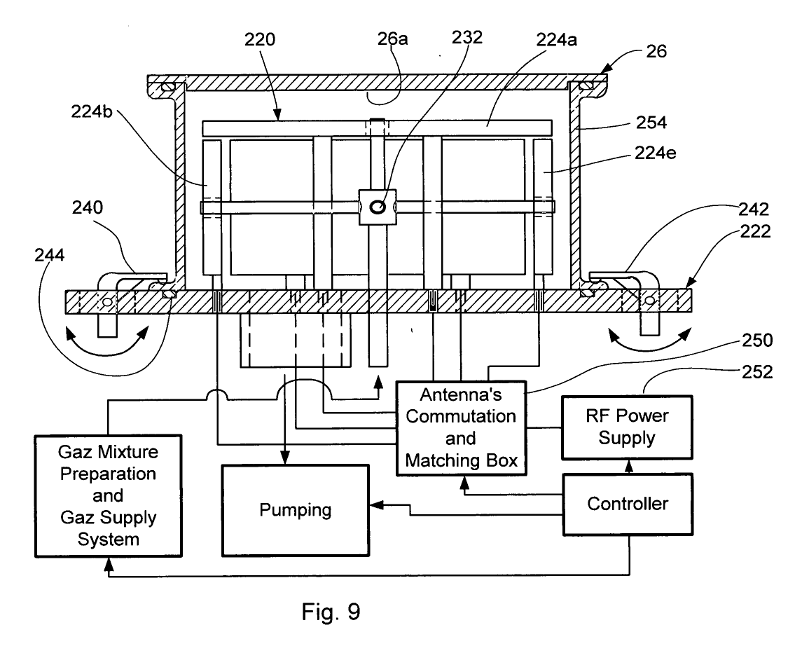

It is understood that one of the inner walls of the container 20 in a sealed state is formed by the cover 26 (FIG. 2). Therefore, the barrier layer must also cover the inner side 26a of the cover 26. The cover coating operation is carried out with the use of the same apparatus 220 (FIG. 8) that is used for coating the walls of the container. As shown in FIG. 9, which illustrates position of the apparatus 220 in the coating operation of the inner surface of the cover 26 with a barrier SiO₂ film, for this operation the apparatus 220 is provided with a special sealable jig 254 in the form of a tubular body that surrounds the antenna, supports the cover 26 on its upper end face, and has a height sufficient for supporting the cover above the upper antenna element 224a of the antenna unit 224. The lower end face of the jig 254 is sealingly supported by the base plate 222 with the use of the sealing element. In the cover-coating operation, only one antenna element, i.e., 224a that faces the cover 26, is energized while the remaining elements are disconnected from the power supply. Such switching is carried out with the use of the commutation and impedance-matching unit 252 (FIGS. 8 and 9) under command of the controller 250a. The cover-treating apparatus can be made without a cover-clamping mechanism since the cover will be pressed to the upper end face of the jig by vacuum generated in a space defined by the inner walls of the jig, the lower face of the cover, and the upper face of the base plate.

In the cover-coating process, the apparatus 220 operates in the same manner as in covering the inner walls of the container.

As has been mentioned above, the SiO₂ barrier layer not only prevents penetration of volatile fragments of the polymers to the surfaces of semiconductor wafers stored in the container, but also imparts to the container walls such properties as washability, resistance to scratching, and resistance to wear.

The method of the invention for coating the inner walls of the wafer container with an easily washable, wear- and scratch-resistant barrier layer impermeable to organic volatile substances of polymer comprises the following steps: providing an apparatus having an antenna unit with a configuration that matches the shape defined by the inner walls of a sealable wafer container; sealingly inserting the antenna unit into the interior of the wafer container so that the elements that form the antenna unit are arranged in proximity to the inner walls of the container; creating a vacuum in the interior of the sealed container by evacuating air from the container; supplying a working gas into the interior of the container; energizing the antenna elements for exciting the plasma inside the container to closely conform to the shape defined by the inner walls of the container; and depositing a continuous and uniform barrier-film layer on the inner walls of the container.

The main distinguishing feature of the method of the invention is that in contrast to other known PECVD processes, the deposition process of the invention is carried out in a vacuum that is induced inside the container, itself, instead of the vacuum chamber into which the containers, such as bottles, are placed for treatment. Another distinguishing feature is the shape of the antenna unit, which closely conforms to the shape defined by the inner walls of the container.

Thus, it has been shown that the present invention provides a method and apparatus for coating the inner walls of sealable wafer containers molded from polymer materials with a thin barrier layer, such as an SiO₂ layer, to prevent diffusion of free radicals of the polymer material of the container casing into the interior space of the container that holds the semiconductor wafers. It is another object to provide the aforementioned method and apparatus for coating the inner walls of the wafer containers with the aforementioned barrier SiO₂ layer, which is easily washable and which is resistant to wear and scratching. The aforementioned layer is applied with the use of the PECVD process. The apparatus of the invention excites an SiO₂-depositing plasma that has high conformity to the shape of the inner surface of the wafer container and is capable of forming an SiO₂ film of highly uniform thickness.

Although the invention has been shown and described with reference to specific embodiments, it is understood that these embodiments should not be construed as limiting the areas of application of the invention and that any changes and modifications are possible, provided these changes and modifications do not depart from the scope of the attached patent claims. For example, the antenna unit may have a configuration different from cube-like or parallelepiped-like and may have a cylindrical shape, or the like. Ceramics other than the machineable glass ceramic known under trademark MACOR® can be used to insulate the flat spiral turns of the antenna. The barrier film, itself, may comprise a diamond-type coating layer. The flat spiral turns of the antenna elements can be made hollow for passing the flow of cooling water. The base plate can be made without the clamping mechanisms since the container will be held in place and pressed to the base plate by vacuum induced inside the container. The apparatus may be made without a gas distribution pipe since one pipe inserted into the container may be sufficient for instant filling of the container's interior with the working gas.

1. An apparatus for application of a thin barrier layer onto inner walls of a sealable wafer container with the use of a plasma-enhanced chemical-vapor-deposition process, the apparatus comprising:
a three-dimensional RF antenna unit that has a shape closely conforming to the shape defined by the aforementioned inner walls of the sealable wafer container;
a base plate that supports the aforementioned RF antenna unit and that has a mechanism for sealing the sealable wafer container to the base plate;
an exhaust pipe that passes through the base plate for connection of the interior of the sealable wafer container with a vacuum system when the sealable wafer container is sealingly attached to the base plate through the aforementioned mechanism for sealing the sealable wafer container to the base plate;
a working gas supply pipe that passes through the base plate to connect the interior of the sealable wafer container with a source of supply of a working gas when the sealable wafer container is sealingly attached to the base plate through the aforementioned mechanism for sealing the sealable wafer container to the base plate;
a commutator and impedance-matching unit connected to the three-dimensional antenna unit; and
an RF power supply connected to the commutator and impedance-matching unit.

2. The apparatus of claim 1, wherein the three-dimensional antenna unit comprises a plurality of flat spiral RF antenna elements connected to each other into a body that conforms to the shape defined by the inner walls of the sealable wafer container, each flat spiral RF antenna element being made of a material having high electrical conductivity, having first and second terminals, and being isolated with an insulation material except said first and second terminals, said first and second terminals being electrically connected to the aforementioned commutator and impedance-matching unit.

3. The apparatus of claim 2, wherein the aforementioned insulation material is ceramic.

4. The apparatus of claim 3, wherein the aforementioned ceramic is a machineable glass ceramic.

5. The apparatus of claim 1, wherein the thin barrier layer is an SiO₂ barrier layer and the aforementioned working gas is a mixture of a gaseous organosilicon compound with excess oxygen.

6. The apparatus of claim 1, wherein the aforementioned mechanism for sealing connection is a standard mechanical interface.

7. The apparatus of claim 2, wherein the aforementioned mechanism for sealing connection is a standard mechanical interface.

8. The apparatus of claim 3, wherein the aforementioned mechanism for sealing connection is a standard mechanical interface.

9. The apparatus of claim 5, wherein the aforementioned mechanism for sealing connection is a standard mechanical interface.

10. The apparatus of claim 7, wherein the aforementioned plurality of flat spiral RF antenna elements is five flat spiral RF antenna elements connected to each other into a body that comprises a cube or parallelepiped.

11. The apparatus of claim 1, further provided with a controller connected to the commutator and impedance-matching unit for switching the antenna unit between the first state, in which all flat spiral RF antenna elements are connected to the RF power supply, and the second state, in which only one flat spiral RF antenna element is connected to the RF power supply.

12. The apparatus of claim 11, further provided with a sealable jig for supporting the container cover in a position opposite said one flat spiral RF antenna element for coating one side of the cover with the aforementioned thin barrier layer when the sealable jig is sealed and connected to the source of vacuum, and when said one flat spiral RF antenna element is energized.

13. The apparatus of claim 12, wherein the thin barrier layer is an SiO₂ barrier layer and the aforementioned working gas is a mixture of a gaseous organosilicon compound with excess oxygen.

14. The apparatus of claim 13, wherein the aforementioned mechanism for sealing connection is a standard mechanical interface.

15. A method for application of a thin barrier layer onto inner walls of a sealable wafer container with the use of a plasma-enhanced chemical-vapor-deposition process for coating the inner walls of the wafer container with an easily washable and wear- and scratch-resistant barrier layer impermeable to organic volatile substances of polymer, the method comprising the steps of:
providing an apparatus having an antenna unit insertable into the sealable wafer container and having a configuration that matches the shape defined by the inner walls of the sealable wafer container;
sealingly inserting the antenna unit into the interior of the sealable wafer container so that the elements that form the antenna unit are arranged in proximity to the inner walls of the container;
creating a vacuum in the interior of the sealed wafer container by evacuating air from the container;
supplying a working gas into the interior of the container;
energizing the antenna elements for exciting the plasma inside the container to closely conform to the shape defined by the inner walls of the container;
causing a plasma-chemical reaction in the vacuum of the container; and
depositing a continuous and uniform barrier-film layer on the inner walls of the container.

16. The method of claim 15, wherein the working gas is a mixture of a gaseous organosilicon substance with excess oxygen and wherein the barrier layer is a silicon dioxide film.

17. The method of claim 15, further comprising the step of providing the aforementioned apparatus with a standard mechanical interface and using the standard mechanical interface for sealing the sealable wafer container in the step of providing a vacuum inside the container.

18. The method of claim 15, wherein the sealable wafer container has a cover, the method further comprising the step of using the apparatus for coating one surface of the aforementioned cover.

19. The method of claim 17, wherein the working gas is a mixture of a gaseous organosilicon substance with excess oxygen and wherein the barrier layer is a silicon dioxide film.

20. The method of claim 19, wherein the silicon dioxide film has a thickness in the range of 100 to 500 Angstroms.
